(19) United States
(12) Patent Application Publication
(10) Pub. No.: US 2023/0411506 A1
(43) Pub. Date: Dec. 21, 2023

(54) NITRIDE SEMICONDUCTOR DEVICE

(71) Applicant: Panasonic Intellectual Property Management Co., Ltd., Osaka (JP)

(72) Inventors: Hideyuki OKITA, Osaka (JP); Manabu YANAGIHARA, Osaka (JP); Masahiro HIKITA, Hyogo (JP)

(21) Appl. No.: 18/247,705

(22) PCT Filed: Oct. 7, 2021
(86) PCT No.: PCT/JP2021/037216

§ 371 Date: Apr. 3, 2023

(30) Foreign Application Priority Data
Oct. 29, 2020 (JP) 2020-181934

(51) Int. Cl. H01L 29/778; H01L 29/423; H01L 29/66

(52) U.S. Cl. CPC H01L 29/7786; H01L 29/4236; H01L 29/66462; H01L 29/2003

(57) ABSTRACT

A nitride semiconductor device includes: a substrate; and a first nitride semiconductor layer, a second nitride semiconductor layer, and a third nitride semiconductor layer that are disposed above the substrate in the stated order. The first nitride semiconductor layer includes a recess. The second nitride semiconductor layer has a band gap larger than a band gap of the first nitride semiconductor layer and is disposed in a region other than the recess. The third nitride semiconductor layer has a band gap larger than the band gap of the first nitride semiconductor layer and covers the first nitride semiconductor layer and the second nitride semiconductor layer including an inner wall of the recess. A contact angle at which a side wall of the recess and an interface between the first nitride semiconductor layer and the second nitride semiconductor layer meet ranges from 140° to less than 180°.

### CROSS-REFERENCE OF RELATED APPLICATIONS

This application is the U.S. National Phase under 35 U.S.C. § 371 of International Patent Application No. PCT/JP2021/037216, filed on Oct. 7, 2021, which in turn claims the benefit of Japanese Patent Application No. 2020-181934, filed on Oct. 29, 2020, the entire disclosures of which Applications are incorporated by reference herein.

### TECHNICAL FIELD

The present disclosure relates to nitride semiconductor devices.

### BACKGROUND ART

Group III nitride semiconductors have wide band gaps and thus have high breakdown voltages. Moreover, the Group III nitride semiconductors can readily form heterostructures such as AlGaN/GaN. Piezoelectric charges produced by the difference in lattice constant between AlGaN and GaN and the difference in band gap between AlGaN and GaN can cause a channel of electrons with high mobility and high concentration (two-dimensional electron gas; 2DEG) to be generated at the interface between AlGaN and GaN adjacent to a GaN layer. Controlling the two-dimensional electron gas can form a high electron mobility transistor (HEMT). Due to the above-described characteristics including high voltage resistance, high speed operability, and large current operability, the Group III nitride semiconductors have been applied to electronic devices including field-effect transistors (FET) and diodes for high power applications.

For example, Patent Literature (PTL) 1 discloses a semiconductor device having a structure with laminated semiconductor layers including a buffer layer, a channel layer composed of GaN, and a lightly C-doped barrier layer composed of AlGaN epitaxially grown in the stated order on a Si substrate. The lightly C-doped barrier layer has a recess, and the recess and the lightly C-doped barrier layer are covered with a heavily C-doped barrier layer. Furthermore, a gate layer is disposed above the recess, and a source electrode and a drain electrode are disposed on the barrier layer on either side of the gate layer to be spaced from the gate layer.

Such a semiconductor device as disclosed in PTL 1 is a field-effect transistor of which the drain current flowing between the source electrode and the drain electrode through a 2DEG layer can be controlled with a voltage applied to the gate layer. Moreover, the length of the opening of the recess in an alignment direction in which the source electrode and the drain electrode are aligned is longer than the length of the bottom of the recess in the alignment direction. That is, the recess has a recessed shape with tapered side walls. The term “tapered” refers to a state where the side walls of the recess are inclined outward to be away from the gate layer by 90° or less with respect to the 2DEG layer.

According to the semiconductor device disclosed in PTL 1, the tapered side walls of the recess can reduce the concentration of the electric field on the edges of the recess, on which the electric field concentrates after the edges of the gate layer.

### CITATION LIST

### Patent Literature

[PTL 1]
Japanese Patent No. 6555542

### SUMMARY OF INVENTION

### Technical Problem

It is conceivable that the on-resistance of the Group III nitride semiconductor device disclosed in PTL 1 can be reduced to some extent using the recessed structure. However, the semiconductor device requires lower on-resistance as a power semiconductor.

In view of this, a principal object of the present disclosure is to provide a nitride semiconductor device of which the on-resistance can be further reduced.

### Solution to Problem

A nitride semiconductor device according to an aspect of the present disclosure includes: a substrate; and a first nitride semiconductor layer, a second nitride semiconductor layer, and a third nitride semiconductor layer that are disposed above the substrate in stated order, wherein the first nitride semiconductor layer includes a recess, the second nitride semiconductor layer has a band gap larger than a band gap of the first nitride semiconductor layer and is disposed in a region other than the recess, the third nitride semiconductor layer has a band gap larger than the band gap of the first nitride semiconductor layer and covers the first nitride semiconductor layer and the second nitride semiconductor layer including an inner wall of the recess, and a contact angle at which a side wall of the recess and an interface between the first nitride semiconductor layer and the second nitride semiconductor layer meet ranges from 140° to less than 180°.

### Advantageous Effects of Invention

In accordance with the nitride semiconductor device according to the present disclosure, the on-resistance can be further reduced.

### BRIEF DESCRIPTION OF DRAWINGS

FIG. 1 is a cross-sectional view of a cross-sectional structure of a nitride semiconductor device according to an embodiment and first and second variations.

FIG. 2 is a diagram illustrating a characteristic of the nitride semiconductor device according to the embodiment.

FIG. 3 is a diagram illustrating a characteristic of the nitride semiconductor device according to the embodiment.

FIG. 4 is a diagram illustrating a characteristic of the nitride semiconductor device according to the second variation of the embodiment.

FIG. 5 is a diagram illustrating a characteristic of the nitride semiconductor device according to the second variation of the embodiment.

FIG. 6 is a cross-sectional view of a cross-sectional structure of a nitride semiconductor device according to third, fourth, fifth, eighth, ninth, and tenth variations of the embodiment.

FIG. 7 is a cross-sectional view of a cross-sectional structure of a nitride semiconductor device according to sixth and seventh variations of the embodiment.

FIG. 8 is a cross-sectional view of a cross-sectional structure of a nitride semiconductor device according to an eleventh variation of the embodiment.

FIG. 9A is a cross-sectional view of a cross-sectional structure of the nitride semiconductor device according to the embodiment in a process of a production method.

FIG. 9B is a cross-sectional view of a cross-sectional structure of the nitride semiconductor device according to the embodiment in a process of a production method.

FIG. 9C is a cross-sectional view of a cross-sectional structure of the nitride semiconductor device according to the embodiment in a process of a production method.

FIG. 9D is a cross-sectional view of a cross-sectional structure of the nitride semiconductor device according to the embodiment in a process of a production method.

FIG. 9E is a cross-sectional view of a cross-sectional structure of the nitride semiconductor device according to the embodiment in a process of a production method.

FIG. 10 is a plan view of a planar structure of the nitride semiconductor device according to the embodiment.

FIG. 11 is a plan view of a planar structure of the nitride semiconductor device according to the embodiment.

### DESCRIPTION OF EMBODIMENTS

### Summary of Present Disclosure

A nitride semiconductor device according to an aspect of the present disclosure includes: a substrate; and a first nitride semiconductor layer, a second nitride semiconductor layer, and a third nitride semiconductor layer that are disposed above the substrate in stated order, wherein the first nitride semiconductor layer includes a recess, the second nitride semiconductor layer has a band gap larger than a band gap of the first nitride semiconductor layer and is disposed in a region other than the recess, the third nitride semiconductor layer has a band gap larger than the band gap of the first nitride semiconductor layer and covers the first nitride semiconductor layer and the second nitride semiconductor layer including an inner wall of the recess, and a contact angle at which a side wall of the recess and an interface between the first nitride semiconductor layer and the second nitride semiconductor layer meet ranges from 140° to less than 180°.

This reduces the bend of two-dimensional electron gas in the vicinity of the contact angle and thus smooths the flow of electrons. Moreover, the concentration of the two-dimensional electron gas in the vicinity of the contact angle increases. As a result, the on-resistance can be reduced, and the maximum drain current can be increased.

For example, the contact angle at which the side wall of the recess and the interface between the first nitride semiconductor layer and the second nitride semiconductor layer meet and a contact angle at which an other side wall of the recess on an opposite side and the interface between the first nitride semiconductor layer and the second nitride semiconductor layer meet may both range from 140° to less than 180°.

This smooths the flow of electrons in the vicinity of the contact angles on both sides of the recess and increases the concentration of the two-dimensional electron gas. As a result, the on-resistance can be further reduced, and the maximum drain current can be further increased.

For example, an average of the contact angle at which the side wall of the recess and the interface between the first nitride semiconductor layer and the second nitride semiconductor layer meet and a contact angle at which an other side wall of the recess on an opposite side and the interface between the first nitride semiconductor layer and the second nitride semiconductor layer meet may range from 145° to less than 180°.

This smooths the flow of electrons in the vicinity of the contact angles on both sides of the recess and increases the concentration of the two-dimensional electron gas. As a result, the on-resistance can be further reduced, and the maximum drain current can be further increased.

For example, the contact angle may be larger than a taper angle at which a side wall of the second nitride semiconductor layer facing the recess and an upper surface of the second nitride semiconductor layer meet.

This enables the nitride semiconductor device to operate at a higher speed with reduced on-resistance and increased maximum drain current.

For example, a taper angle at which a side wall of the second nitride semiconductor layer facing the recess and an upper surface of the second nitride semiconductor layer meet may range from 120° to less than 180°.

This uniformizes the film thickness and/or composition of the third nitride semiconductor layer. As a result, the on-resistance can be further reduced, and the maximum drain current can be further increased.

For example, a difference between the contact angle and a taper angle at which a side wall of the second nitride semiconductor layer facing the recess and an upper surface of the second nitride semiconductor layer meet may be within a range of ±20°.

This reduces the on-resistance, increases the maximum drain current, and enables higher speed operation.

For example, a gradient of a tangent to the side wall of the recess and a gradient of a tangent to a side wall of the second nitride semiconductor layer facing the recess may be uniquely determined.

This uniformizes the film thickness and/or composition of the third nitride semiconductor layer. As a result, the on-resistance can be further reduced, and the maximum drain current can be further increased.

For example, an angle formed between the side wall of the recess and a side wall of the second nitride semiconductor layer facing the recess may be within a range of 180°±30°.

This uniformizes the film thickness and/or composition of the third nitride semiconductor layer. As a result, the on-resistance can be further reduced, and the maximum drain current can be further increased.

For example, a film thickness of a part of the third nitride semiconductor layer along a side wall of the second nitride semiconductor layer may be more than or equal to 50% of a film thickness of a part of the third nitride semiconductor layer along a bottom of the recess in a vertical direction.

This uniformizes the film thickness and/or composition of the third nitride semiconductor layer. As a result, the on-resistance can be further reduced, and the maximum drain current can be further increased.

For example, the third nitride semiconductor layer may contain Al, and an Al composition in the third nitride semiconductor layer may be less than or equal to 25%.

This reduces the leakage current.

For example, the third nitride semiconductor layer may contain Al, and an Al composition in the third nitride semiconductor layer may vary within a range of ±5%.

This uniformizes the composition of the third nitride semiconductor layer. As a result, the on-resistance can be further reduced, and the maximum drain current can be further increased.

For example, the nitride semiconductor device according to an aspect of the present disclosure may further include a source electrode and a drain electrode spaced from the recess with the recess disposed therebetween, wherein a contact angle adjacent to the drain electrode may be larger than a contact angle adjacent to the source electrode.

As the contact angle adjacent to the drain electrode increases, the concentration of the electric field adjacent to the drain electrode decreases, and thus the gate leakage current decreases. As the contact angle adjacent to the source electrode decreases, the gate-source capacitance decreases, enabling the nitride semiconductor device to operate at a higher speed.

Hereinafter, a nitride semiconductor device according to an embodiment will be described with reference to the accompanying drawings.

Note that the embodiment described below illustrates a specific example of the present disclosure. The numerical values, shapes, materials, constituent elements, the arrangement and connection of the constituent elements, etc. illustrated in the embodiment below are mere examples, and do not intend to limit the present disclosure. Moreover, among the constituent elements included in the embodiment below, constituent elements not recited in any of the independent claims will be described as optional constituent elements.

Note that the drawings are represented schematically and are not necessarily precise illustrations. Thus, the scales of the drawings, for example, are not necessarily precise. Moreover, in the drawings, essentially the same constituent elements share the same reference signs, and redundant descriptions will be omitted or simplified.

In the Specification, numerical values and terms representing relationships between elements such as “parallel”, “orthogonal”, and “identical” do not represent their strict meanings only, but include a substantially equivalent range, for example deviations of about a few percent.

Note that in the Specification, the terms “above” and “below” do not refer to the upward direction (vertically up) and the downward direction (vertically down) of the spatial recognition in the absolute sense, but are used as terms defined according to a relative positional relationship based on the order in which layers are laminated for forming a layered structure. Moreover, the terms “above” and “below” are used not only when two constituent elements are disposed apart from each other and there is another constituent element present between the two constituent elements, but also when two constituent elements are disposed in close contact with each other and no other element is present between the two constituent elements.

Specifically, “above” represents the direction in which semiconductor layers, gate electrodes, drain electrodes, source electrodes, and so on are located relative to a substrate. Moreover, main surfaces of the semiconductor layers and those of the electrodes adjacent to the substrate may be described as “lower surfaces”, and main surfaces on the opposite side may be described as “upper surfaces”.

In the Specification, unless otherwise noted, “in plan view” refers to viewing main surfaces of the substrate directly toward the main surfaces, that is, viewing the main surfaces of the substrate in a direction orthogonal to the main surfaces. Moreover, the direction orthogonal to the main surfaces of the substrate corresponds to the thickness direction of the substrate, which is the direction of lamination of the layers.

Moreover, in the Specification, “in a sectional view” refers to viewing a predetermined section directly toward the predetermined section. Unless otherwise noted, the predetermined section is a section of the nitride semiconductor device cut by a plane orthogonal to the main surfaces of the substrate and parallel to an alignment direction in which the source electrodes, the gate electrodes, and drain electrodes are aligned.

In the Specification, unless otherwise noted, the use of ordinal numbers, such as “first” and “second”, is to avoid confusion among constituent elements of the same kind and to distinguish respective constituent elements rather than to denote the number or the order of the constituent elements.

### Embodiment

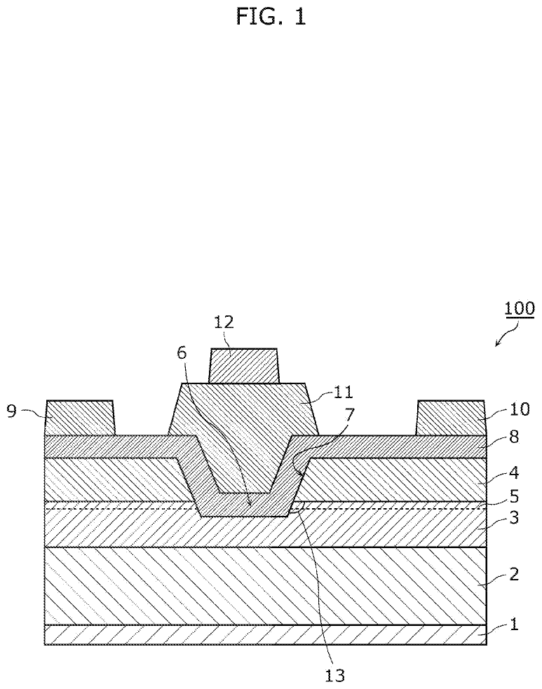

In a nitride semiconductor device according to an embodiment, the contact angles at which the side walls of a recess and the interface between a channel layer and a barrier layer meet range from 140° to less than 180°. First, a structure of the nitride semiconductor device according to the embodiment will be described with reference to FIG. 1. FIG. 1 is a cross-sectional view of a cross-sectional structure of nitride semiconductor device 100 according to this embodiment.

Nitride semiconductor device 100 illustrated in FIG. 1 includes appropriate substrate 1 composed of Si (or, for example, a substrate composed of sapphire, SiC, GaN, AlN, or the like) and appropriate buffer layer 2 (for example, a single layer film composed of a Group III nitride semiconductor including GaN, AlGaN, AlN, InGaN, InN, and AlInGaN or a multilayer film composed thereof) disposed on substrate 1. Nitride semiconductor device 100 includes channel layer 3 composed of GaN (or, for example, a Group III nitride semiconductor including InGaN, InN, AlGaN, and AlInGaN) on buffer layer 2, and includes first barrier layer 4 composed of AlGaN (or, for example, a Group III nitride semiconductor including GaN, InGaN, AlGaN, AlN, and AlInGaN) disposed on channel layer 3. Channel layer 3 is an example of a first nitride semiconductor layer. First barrier layer 4 is an example of a second nitride semiconductor layer. In a case where first barrier layer 4 has a band gap larger than that of channel layer 3 and where first barrier layer 4 and channel layer 3 are composed of AlGaN and GaN, respectively, piezoelectric charges produced by the difference in lattice constant between AlGaN and GaN and the difference in band gap between AlGaN and GaN cause high-concentration two-dimensional electron gas (2DEG) layer 5 to be generated in channel layer 3 adjacent to the interface between first barrier layer 4 and channel layer 3.

Channel layer 3 and first barrier layer 4 are provided with recess 6 that passes through first barrier layer 4 from the upper surface to reach channel layer 3. Nitride semiconductor device 100 includes second barrier layer 8 composed of AlGaN (or, for example, a Group III nitride semiconductor including GaN, InGaN, AlGaN, AlN, and AlInGaN) formed to cover recess 6, side walls 7 of the recess, and the uppermost surface of first barrier layer 4. Side walls 7 of the recess refer to side walls (end faces) of first barrier layer 4 facing recess 6. Second barrier layer 8 is an example of a third nitride semiconductor layer that at least partially extends along the inner surfaces (bottom and side walls) of recess 6. In a case where second barrier layer 8 also has a band gap larger than that of channel layer 3 and where second barrier layer 8 and channel layer 3 are composed of AlGaN and GaN, respectively, piezoelectric charges produced by the difference in lattice constant between AlGaN and GaN and the difference in band gap between AlGaN and GaN cause a high-concentration 2DEG layer to be generated (when the nitride semiconductor device is on; not illustrated) in channel layer 3 adjacent to the interface between second barrier layer 8 and channel layer 3.

Nitride semiconductor device 100 includes selectively formed gate layer 11 composed of p-GaN (or, for example, a Group III nitride semiconductor including p-InGaN, p-InN, p-AlGaN, and p-AlInGaN) containing a p-type impurity (Mg, Zn, C, or the like) disposed above recess 6. Gate layer 11 may be composed of, for example, p-GaN containing Mg, composed of i-GaN (Insulated-GaN) (or, for example, a Group III nitride semiconductor including i-GaN, i-InGaN, i-InN, i-AlGaN, and i-AlInGaN) containing C or the like, or composed of n-GaN (or, for example, a Group III nitride semiconductor including n-InGaN, n-AlGaN, n-InN, and n-AlInGaN) containing an n-type impurity, such as Si. In nitride semiconductor device 100, the strength of the electric field is high at an end of gate layer 11 adjacent to drain electrode 10. Accordingly, it is desirable that a part with a large total film thickness of first barrier layer 4 and second barrier layer 8 be covered with gate layer 11 at the end of gate layer 11. That is, gate layer 11 may cover at least a part of recess 6 adjacent to drain electrode 10 or may cover the entire opening of recess 6.

Nitride semiconductor device 100 includes source electrode 9 and drain electrode 10 disposed on second barrier layer 8 on either side of gate layer 11 to be spaced from gate layer 11. Each of source electrode 9 and drain electrode 10 is an electrode composed of one or a combination of two or more of metals including Ti, Al, Mo, and Hf in ohmic contact with 2DEG layer 5, first barrier layer 4, second barrier layer 8, or channel layer 3, and need only be electrically connected to 2DEG layer 5. For example, source electrode 9 and drain electrode 10 may be disposed on the surface of second barrier layer 8 or first barrier layer 4, and may be in contact with 2DEG layer 5, first barrier layer 4, or channel layer 3 using a known ohmic recess technique (not illustrated).

Nitride semiconductor device 100 includes gate electrode 12 on gate layer 11. Gate electrode 12 may be disposed on gate layer 11 as illustrated in FIG. 1. In a case where gate layer 11 is not provided, a so-called MES structure in which gate electrode 12 is in direct contact with second barrier layer 8 may be used (not illustrated). In the case of the MES structure, gate electrode 12 serves as an electrode in Schottky contact with second barrier layer 8 in an upper part of recess 6. A so-called MIS structure with an insulating film such as SiNx, SiOx, or AIOx disposed between gate electrode 12 and second barrier layer 8 instead of gate layer 11 under gate electrode 12 or a MOS structure may also be used (not illustrated).

From a safety standpoint, power semiconductors are expected to operate in a normally off mode. In the case where gate layer 11 is composed of a p-type Group III nitride semiconductor, a p-n junction is formed in the vicinity of recess 6 immediately under gate layer 11, and two-dimensional electron gas is depleted while a gate voltage is not applied to gate electrode 12. This causes the device to enter a so-called normally off state. At that moment, in a case where second barrier layer 8 is composed of AlGaN and where the Al composition in AlGaN of second barrier layer 8 is 20%, the film thickness of second barrier layer 8, which may vary depending on a set threshold voltage (Vth), needs to be within a range from 10 to 25 nm, desirably about 20 nm, at a part immediately under gate layer 11. Moreover, at that moment, in the case where gate layer 11 is composed of p-GaN, the film thickness of gate layer 11 may be within a range from 50 to 500 nm, desirably about 200 nm. Moreover, in the case where the p-type impurity in gate layer 11 is Mg, the doping concentration may be within a range from 1E19 cm⁻³ to 10E19 cm⁻³, desirably 5E19 cm⁻³. The carrier concentration of p-GaN doped with Mg of about 5E19 cm⁻³ substantially ranges from about 1E17 cm⁻³ to about 5E17 cm⁻³ due to a very low activation rate of Mg, which is a few percent or less. Nitride semiconductor device 100 illustrated in FIG. 1 includes no two-dimensional electron gas immediately under recess 6 due to depletion and is in the normally off state.

Gate electrode 12 need only be an electrode composed of one or a combination of two or more of metals including Ti, Ni, Pd, Pt, Au, W, WSi, Ta, TiN, Al, Mo, Hf, and Zr. In the case where gate layer 11 is composed of a p-type Group III nitride semiconductor, gate electrode 12 may be in ohmic contact or Schottky contact with gate layer 11. However, since ohmic contact increases the reliability of the gate electrode, it is desirable that an electrode composed of one or a combination of two or more of metals including Ni, Pt, Pd, Au, Ti, Cr, In, Sn, and Al, which have low contact resistances, be used as gate electrode 12.

In nitride semiconductor device 100 according to this embodiment, contact angles 13 at which the side walls of the recess and the interface between first barrier layer 4 and channel layer 3 meet range from 140° to less than 180°.

### [Operation]

Next, the operation of nitride semiconductor device 100 according to this embodiment will be described.

In a case where nitride semiconductor device 100 is a FET that uses p-GaN for gate layer 11 and that operates in the normally off mode, the depletion layer formed in the p-n junction extends immediately under gate layer 11 when the voltage applied to gate electrode 12 is 0 V. Accordingly, two-dimensional electron gas does not exist, and nitride semiconductor device 100 is in an off state (FIG. 1). As a positive gate voltage is applied to gate electrode 12 while a positive voltage is applied to drain electrode 10 with source electrode 9 grounded, the depletion layer formed in the p-n junction immediately under gate layer 11 decreases. When the gate voltage exceeds the threshold voltage (Vth), a source-drain current starts flowing, and thus nitride semiconductor device 100 enters an on state (not illustrated). That is, application of voltage to gate electrode 12 allows control of the source-drain current.

### Effects and the Like

Next, the effects of nitride semiconductor device 100 according to this embodiment will be described. According to this embodiment, the concentration of two-dimensional electron gas immediately under the side walls of recess 6 can be increased, the on-resistance can be significantly reduced, and the maximum drain current can be significantly increased.

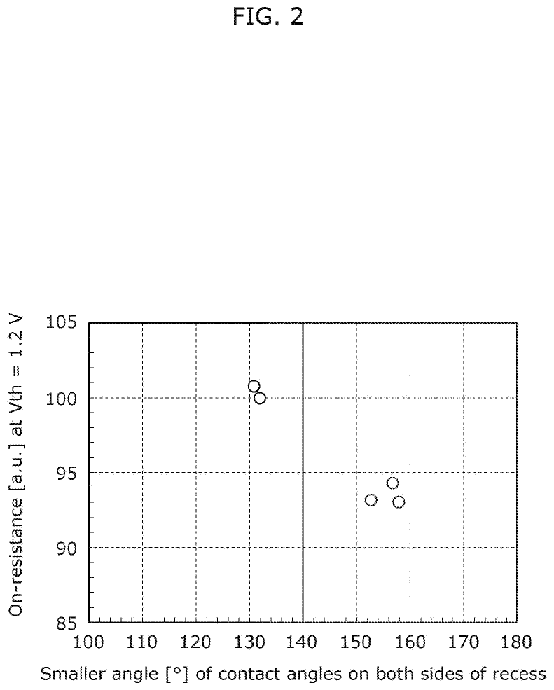

FIG. 2 is a correlation chart between smaller contact angle 13 of contact angles 13 on both sides, adjacent to source electrode 9 and drain electrode 10, of recess 6 and the on-resistance normalized by the threshold voltage of 1.2 V. As is clear from FIG. 2, the on-resistance significantly decreases as smaller contact angle 13 increases and exceeds 140°.

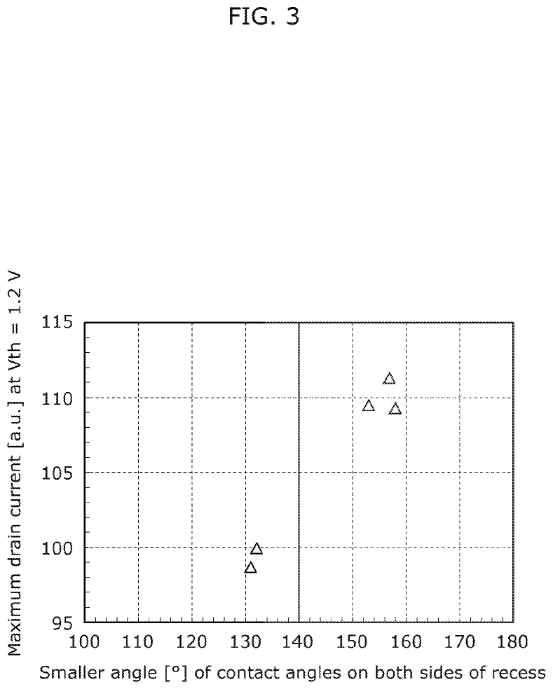

FIG. 3 is a correlation chart between smaller contact angle 13 of contact angles 13 on both sides, adjacent to source electrode 9 and drain electrode 10, of recess 6 and the normalized maximum drain current. As is clear from FIG. 3, the maximum drain current significantly increases as smaller contact angle 13 increases and exceeds 140°.

These improvements in characteristic result from smoother flow of electrons caused by reduced bend of 2DEG layer 5 in the vicinity of contact angles 13 of recess 6 and from an increase in the concentration of the two-dimensional electron gas in the vicinity of contact angles 13 due to an increase in contact angles 13. Note that maximum contact angles 13 are less than 180° because recess 6 passes through first barrier layer 4 from the upper surface to reach channel layer 3.

### [First Variation]

Next, a nitride semiconductor device according to a first variation of the embodiment will be described. The structure of the nitride semiconductor device according to this variation is substantially identical to that in the embodiment and will be described with reference to FIG. 1.

In the first variation of the embodiment, contact angles 13 on both sides, adjacent to source electrode 9 and drain electrode 10, of recess 6 range from 140° to less than 180°. Group III nitride semiconductors are used in the description of this variation. However, this should not be construed as limiting the present disclosure. Moreover, the structure of the nitride semiconductor device according to this variation illustrated herein is minimal, and this should not be construed as limiting the present disclosure.

This variation can be used to increase the concentration of the two-dimensional electron gas immediately under the side walls of recess 6, reduce the on-resistance, and increase the maximum drain current in addition to the effects of the embodiment.

The on-resistance and the maximum drain current depend on the total resistance between source electrode 9 and drain electrode 10. In the nitride semiconductor device according to this variation, contact angles 13 on both sides, adjacent to source electrode 9 and drain electrode 10, of recess 6 in the embodiment illustrated in FIG. 1 range from 140° to less than 180°. This can minimize the resistance at either contact angle 13 and, as a result, reduce the on-resistance and further increase the maximum drain current.

### [Second Variation]

Next, a nitride semiconductor device according to a second variation of the embodiment will be described. The structure of the nitride semiconductor device according to this variation is substantially identical to that in the embodiment and will be described with reference to FIG. 1.

In the second variation of the embodiment, the average of contact angles 13 on both sides, adjacent to source electrode 9 and drain electrode 10, of recess 6 ranges from 145° to less than 180°. Group III nitride semiconductors are used in the description of this variation. However, this should not be construed as limiting the present disclosure. Moreover, the structure of the nitride semiconductor device according to this variation illustrated herein is minimal, and this should not be construed as limiting the present disclosure.

This variation can be used to increase the concentration of the two-dimensional electron gas immediately under the side walls of recess 6, reduce the on-resistance, and increase the maximum drain current in addition to the effects of the embodiment or the first variation.

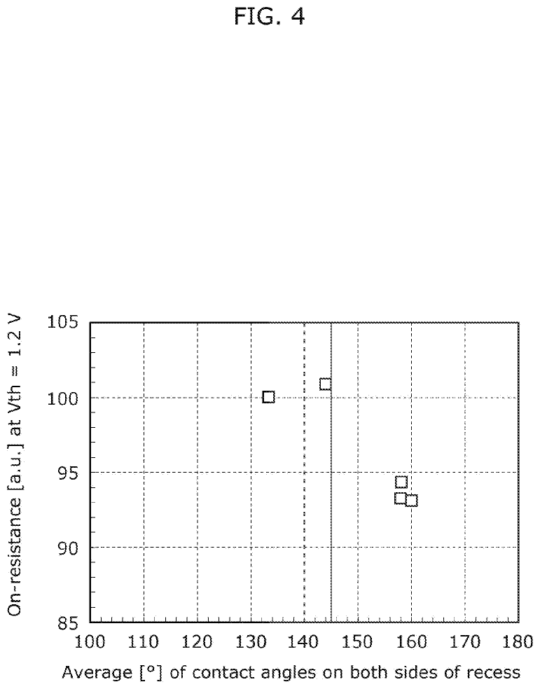

FIG. 4 is a correlation chart between the average of contact angles 13 on both sides, adjacent to source electrode 9 and drain electrode 10, of recess 6 and the on-resistance normalized by the threshold voltage of 1.2 V. As illustrated in FIG. 4, the on-resistance significantly decreases as the average of contact angles 13 increases and exceeds 145°.

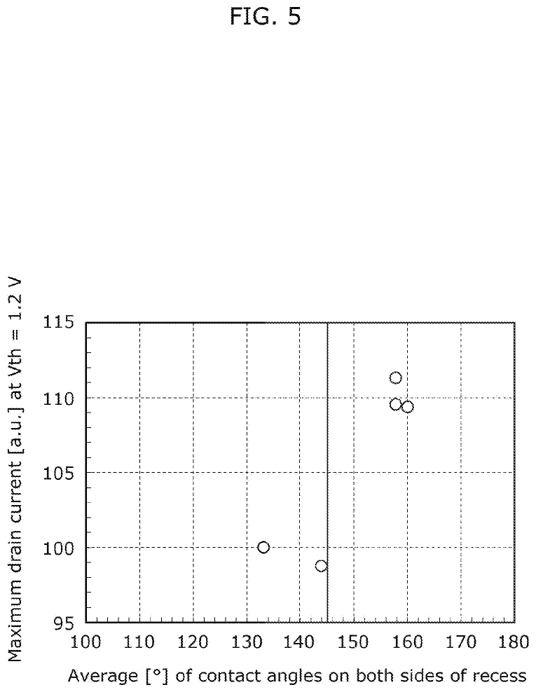

FIG. 5 is a correlation chart between the average of contact angles 13 on both sides, adjacent to source electrode 9 and drain electrode 10, of recess 6 and the normalized maximum drain current. As illustrated in FIG. 5, the maximum drain current significantly increases as the average of contact angles 13 increases and exceeds 145° as in the case of the on-resistance.

These improvements in characteristic result from smoother flow of electrons caused by reduced bend of 2DEG layer 5 in the vicinity of contact angles 13 on both sides of recess 6 and from an increase in the concentration of the two-dimensional electron gas in the vicinity of contact angles 13 due to an increase in the average of contact angles 13 to more than 145°. As a result, the on-resistance can be reduced, and the maximum drain current can be further increased. Note that maximum contact angles 13 are less than 180° because recess 6 passes through first barrier layer 4 from the upper surface to reach channel layer 3.

### [Third Variation]

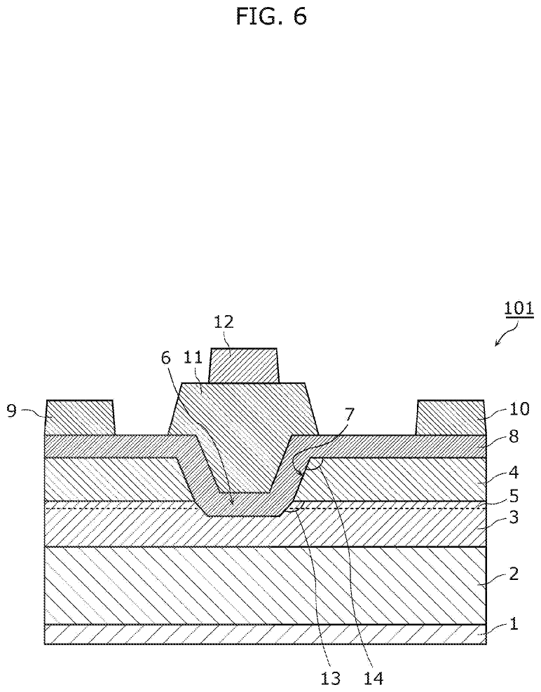

Next, a nitride semiconductor device according to a third variation of the embodiment will be described with reference to FIG. 6. FIG. 6 illustrates a cross-sectional structure of nitride semiconductor device 101 according to the third variation of the embodiment. As illustrated in FIG. 6, in nitride semiconductor device 101 according to this variation, contact angles 13 formed between side walls 7 of the recess and the interface between channel layer 3 and first barrier layer 4 are larger than taper angles 14 at which side walls 7 of the recess and the uppermost surface of first barrier layer 4 meet.

In the third variation of the embodiment, contact angles 13 formed between side walls 7 of the recess and the interface between channel layer 3 and first barrier layer 4 are larger than taper angles 14 at which side walls 7 of the recess and the uppermost surface of second barrier layer 8 meet. Note that taper angles 14 are defined as angles at which side walls 7 of the recess and the uppermost surface of second barrier layer 8 meet and that are located on a side of second barrier layer 8 adjacent to the uppermost surface. However, in a case where side walls 7 of the recess are not straight, that is, curved, concaved, or convexed, taper angles 14 are defined as angles at which the extension lines of tangents to the steepest parts of side walls 7 of the recess and the extension line of the uppermost surface of second barrier layer 8 meet. Group III nitride semiconductors are used in the description of this variation. However, this should not be construed as limiting the present disclosure. Moreover, the structure of nitride semiconductor device 101 according to this variation illustrated herein is minimal, and this should not be construed as limiting the present disclosure.

This variation can be used to minimize the horizontal length of gate layer 11, that is, the length of gate layer 11 in a direction from source electrode 9 to drain electrode 10 in addition to the effects of the embodiment or the first or second variation. This can reduce the gate capacitance (gate-source capacitance and gate-drain capacitance) and, as a result, enables nitride semiconductor device 101 to operate at a higher speed.

It is desirable that a part with the largest total film thickness of first barrier layer 4 and second barrier layer 8 be covered with gate layer 11 at an end of gate layer 11 adjacent to drain electrode 10, the electric field being typically high at the end in nitride semiconductor device 101. This is because the effects of electrons or holes trapped by the high electric field at, for example, the surface level of a semiconductor surface can be physically kept away from 2DEG layer Thus, a so-called current collapse (current slump) can be inhibited.

However, in a case where taper angles 14 are large, the end of gate layer 11 adjacent to drain electrode 10 needs to be extended toward drain electrode 10 to cover the part with the large total film thickness of first barrier layer 4 and second barrier layer 8, resulting in an increase in the gate-drain capacitance. In addition, in a typical semiconductor process, gate layer 11 is also extended toward source electrode 9 as taper angles 14 increase. In this case, the gate-source capacitance also increases. The gate capacitance (gate-source capacitance and gate-drain capacitance) is a parameter that is directly linked to the operating speed of nitride semiconductor device 101. A high gate capacitance results in an impairment in the high speed operability of nitride semiconductor device 101. In this variation, the length of gate layer 11 in the direction from source electrode 9 to drain electrode 10 can be minimized. This can reduce the gate capacitance (gate-source capacitance and gate-drain capacitance) and thus enables nitride semiconductor device 101 to operate at a higher speed.

### [Fourth Variation]

Next, a nitride semiconductor device according to a fourth variation of the embodiment will be described. The structure of the nitride semiconductor device according to this variation is substantially identical to that in the third variation of the embodiment and will be described with reference to FIG. 6. In the fourth variation of the embodiment, taper angles 14 at which side walls 7 of the recess and the uppermost surface of first barrier layer 4 meet range from 120° to less than 180°. Group III nitride semiconductors are used in the description of this variation. However, this should not be construed as limiting the present disclosure. Moreover, the structure of the nitride semiconductor device according to this variation illustrated herein is minimal, and this should not be construed as limiting the present disclosure.

This variation can be used to uniformize the film thickness and/or composition of second barrier layer 8, reduce the on-resistance, and increase the maximum drain current in addition to the effects of the embodiment or the first, second, or third variation.

In a case where taper angles 14 are small, that is, side walls 7 of the recess are steep, the film thicknesses of parts of second barrier layer 8, which is formed by epitaxial regrowth, in contact with side walls 7 of the recess are small. This is because, in a case where second barrier layer 8 is grown with a Group III nitride semiconductor containing Al by metal-organic chemical vapor deposition (MOCVD), the lateral epitaxial growth rate is extremely slow compared with the longitudinal epitaxial growth rate. Thus, the film thickness of second barrier layer 8 in contact with side walls 7 of the recess is extremely small, or the Al composition is nonuniform, that is, extremely high or low. As a result, the concentration of 2DEG layer 5 immediately under second barrier layer 8 is locally reduced. Moreover, in a case where taper angles 14 of the Group III nitride semiconductor are close to 120°, the film thickness of second barrier layer 8 may be nonuniform due to facets created in crystal orientations, or voids may be created. Thus, the concentration of 2DEG layer 5 immediately under second barrier layer 8 is locally reduced. These local reductions in the concentration of 2DEG layer 5 increase the on-resistance and reduce the maximum drain current. Accordingly, it is desirable that taper angles 14 range from 120° to less than 180°.

### [Fifth Variation]

Next, a nitride semiconductor device according to a fifth variation of the embodiment will be described. The structure of the nitride semiconductor device according to this variation is substantially identical to that in the third variation of the embodiment and will be described with reference to FIG. 6. In the fifth variation of the embodiment, the differences between contact angles 13 and taper angles 14 are within a range of ±20°. Group III nitride semiconductors are used in the description of this variation. However, this should not be construed as limiting the present disclosure. Moreover, the structure of the nitride semiconductor device according to this variation illustrated herein is minimal, and this should not be construed as limiting the present disclosure.

This variation can be used to uniformize the film thickness and/or composition of second barrier layer 8, reduce the on-resistance, increase the maximum drain current, and reduce the gate capacitance in addition to the effects of the embodiment or the first, second, third, or fourth variation.

In this variation, as illustrated in the embodiment, it is desirable that contact angles 13 range from 140° to less than 180°. Moreover, as illustrated in the fourth variation of the embodiment, it is desirable that taper angles 14 range from 120° to less than 180°. That is, it is desirable that contact angles 13 be different from taper angles 14 by +20° or less (“+” means that the contact angles are larger than the taper angles). Moreover, as illustrated in the third variation of the embodiment, in a case where taper angles 14 are too large compared with contact angles 13, the gate capacitance (gate-source capacitance and gate-drain capacitance) increases, resulting in an impairment in the high speed operation of the nitride semiconductor device. Accordingly, it is desirable that contact angles 13 be different from taper angles 14 by −20° or more (“−” means that the taper angles are larger than the contact angles).

### [Sixth and Seventh Variations]

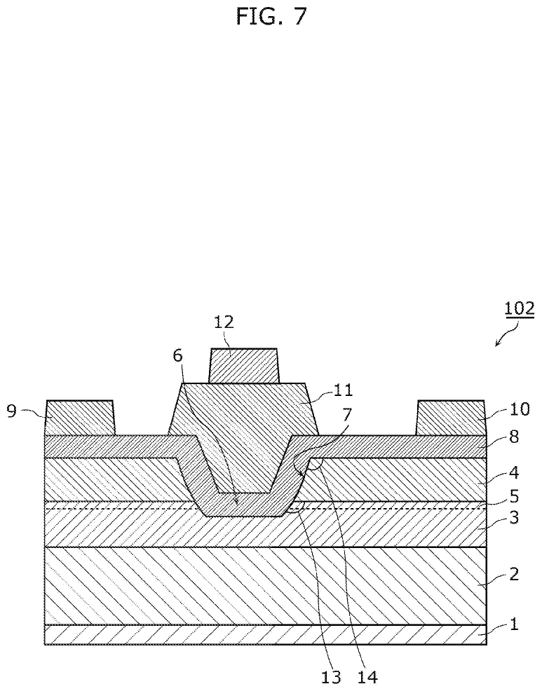

Next, a nitride semiconductor device according to a sixth variation and a seventh variation of the embodiment will be described with reference to FIG. 7. FIG. 7 is a cross-sectional view of a cross-sectional structure of nitride semiconductor device 102 according to the sixth and seventh variations of the embodiment.

As illustrated in FIG. 7, in nitride semiconductor device 102 according to these variations, the gradients of tangents to the side walls of recess 6 (parts that form contact angles 13) and those to the side walls of first barrier layer 4 facing recess 6 are uniquely determined (the side walls are sufficiently smooth). That is, first barrier layer 4 and channel layer 3 that constitute side walls 7 of the recess are continuously connected.

Moreover, in the seventh variation of the embodiment, the sums of contact angles 13 and the angles at which the interface between channel layer 3 and first barrier layer 4 and the side walls of first barrier layer 4 meet, that is, the angles at the lower end of first barrier layer 4 (not illustrated) are within a range of 180°±30°. Group III nitride semiconductors are used in the description of these variations. However, this should not be construed as limiting the present disclosure. Moreover, the structure of nitride semiconductor device 102 according to these variations illustrated herein is minimal, and this should not be construed as limiting the present disclosure.

These variations can be used to uniformize the film thickness and/or composition of second barrier layer 8 in contact with side walls 7 of the recess, accordingly uniformize the concentration of the two-dimensional electron gas immediately under recess 6 and in the vicinity of contact angles 13 while the device is on (not illustrated), reduce the on-resistance, and increase the maximum drain current in addition to the effects of the embodiment or the first, second, third, fourth, or fifth variation.

In a case where taper angles 14 are close to or smaller than 120°, the angles at the lower ends of the side walls of first barrier layer 4 facing recess 6 may be steeper than the angles obtained by subtracting taper angles 14 from 180° (for example, 60° when taper angles 14 are 120°). That is, the angles of the side walls of first barrier layer 4 facing recess 6 become steeper (more vertical) downward. This is because, during the regrowth process of second barrier layer 8, channel layer 3 immediately under the lower ends of the side walls of first barrier layer 4 facing recess 6 is etched by high temperature and hydrogen, which is a carrier gas, during the regrowth and dissolved together with first barrier layer 4 on channel layer 3. Thus, the angles at the lower ends of the side walls of first barrier layer 4 facing recess 6 become steeper than the angles obtained by subtracting taper angles 14 from 180°. This reduces the lateral growth rate of second barrier layer 8 that grows on side walls 7 of the recess, causes the film thickness and/or composition of second barrier layer 8 that grows while being in contact with side walls 7 of the recess to be nonuniform, reduces the two-dimensional electron gas around contact angles 13, increases the on-resistance, and reduces the maximum drain current.

To inhibit this, it is desirable that the side walls of recess 6 (parts that form contact angles 13) and the side walls of first barrier layer 4 facing recess 6 be sufficiently smooth such that the gradients of the tangents are uniquely determined. That is, it is desirable that first barrier layer 4 and channel layer 3 facing recess 6 be continuously connected. Specifically, it is desirable that the sums of contact angles 13 and the angles at the lower ends of the side walls of first barrier layer 4 facing recess 6 (not illustrated) be within the range of 180°±30°. This inhibits the film thickness and/or composition of second barrier layer 8 that grows while being in contact with side walls 7 of the recess from being nonuniform.

### [Eighth, Ninth, and Tenth Variations]

Next, a nitride semiconductor device according to an eighth variation, a ninth variation, and a tenth variation of the embodiment will be described. The structure of the nitride semiconductor device according to these variations is substantially identical to that in the third variation of the embodiment and will be described with reference to FIG. 6.

In the eighth variation of the embodiment, the film thickness of a part of second barrier layer 8 in contact with side walls 7 of the recess is more than or equal to 50% of the film thickness of a part of second barrier layer 8 along the bottom of recess 6 in the vertical direction. In the ninth variation of the embodiment, the Al composition in second barrier layer 8 ranges from 10% to 25%. In the tenth variation of the embodiment, the Al composition in second barrier layer 8 varies within a range of ±5%. Group III nitride semiconductors are used in the description of these variations. However, this should not be construed as limiting the present disclosure. Moreover, the structure of the nitride semiconductor device according to these variations illustrated herein is minimal, and this should not be construed as limiting the present disclosure.

These variations can be used to uniformize the film thickness and/or composition of second barrier layer 8 in contact with side walls 7 of the recess, accordingly uniformize the two-dimensional electron gas immediately under recess 6 while the device is on (not illustrated), reduce the on-resistance, and increase the maximum drain current in addition to the effects of the embodiment or the first, second, third, fourth, fifth, sixth, or seventh variation.

As illustrated in the embodiment or the first, second, third, fourth, fifth, sixth, or seventh variation, larger contact angles 13 or taper angles 14 and the continuous connection of first barrier layer 4 and channel layer 3 that constitute side walls 7 of the recess can uniformize the film thickness of second barrier layer 8 regrown on first barrier layer 4, on recess 6, and on side walls 7 of the recess. This is because side walls 7 of the recess do not become steep (closer to vertical) and second barrier layer 8 is accordingly not affected by the lateral growth rate, at which it regrows slower.

It is desirable that the film thickness of the part of second barrier layer 8 in contact with side walls 7 of the recess be more than or equal to 50% of the film thickness of the part of second barrier layer 8 along the bottom of recess 6 in the vertical direction. This is because the two-dimensional electron gas immediately under recess 6 while the device is on (not illustrated) can be uniformized, the on-resistance can be reduced, and the maximum drain current can be increased. In addition, this can also uniformize the Al composition in second barrier layer 8, and the Al composition in second barrier layer 8 can be brought into the range from 10% to 25%. It is desirable that the Al composition in second barrier layer 8 be more than or equal to 10% because second barrier layer 8 with the Al composition of less than 10% causes the source leakage current (drain-source leakage current) in the nitride semiconductor device. Moreover, it is desirable that the Al composition in second barrier layer 8 be less than or equal to 25% because second barrier layer 8 with the Al composition of more than 25% has an increased gate leakage current in the nitride semiconductor device. In addition, it is desirable that the Al composition in second barrier layer 8 be as uniform as possible to uniformize the two-dimensional electron gas immediately under recess 6 while the device is on (not illustrated). Specifically, it is desirable that the Al composition in second barrier layer 8 vary within the range of ±5%.

### [Eleventh Variation]

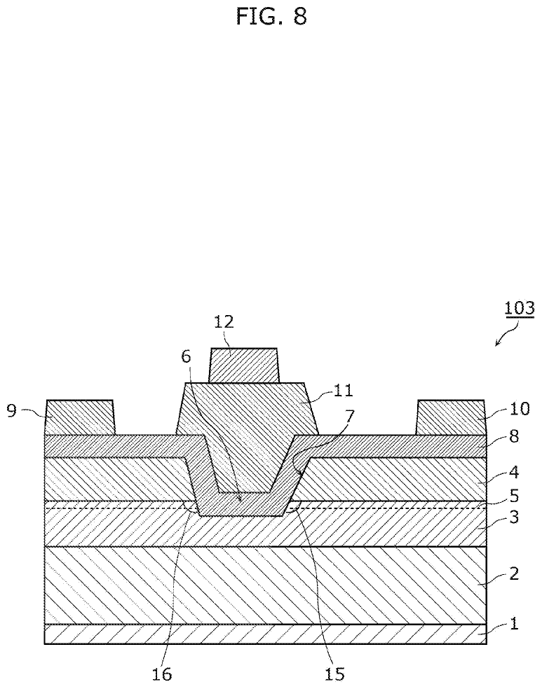

Next, a nitride semiconductor device according to an eleventh variation of the embodiment will be described with reference to FIG. 8. FIG. 8 is a cross-sectional view of a cross-sectional structure of nitride semiconductor device 103 according to the eleventh variation of the embodiment. As illustrated in FIG. 8, in nitride semiconductor device 103 according to this variation, contact angle 15, of contact angles on both sides of recess 6, adjacent to the drain is larger than contact angle 16 adjacent to the source. Group III nitride semiconductors are used in the description of this variation. However, this should not be construed as limiting the present disclosure. Moreover, the structure of nitride semiconductor device 103 according to this variation illustrated herein is minimal, and this should not be construed as limiting the present disclosure.

This variation can be used to reduce the concentration of the electric field of a part of gate layer 11 adjacent to drain electrode 10, the strength of the electric field being the highest at the part in nitride semiconductor device 103, and thus reduce the gate leakage current in addition to the effects of the embodiment or the first, second, third, fourth, fifth, sixth, seventh, eighth, ninth, or tenth variation. This is because gentle contact angle 15 adjacent to the drain causes a part of gate layer 11 adjacent to the drain immediately above contact angle 15 to function as a field plate due to its forward tapered shape and thus to reduce the non-uniformity of the electric field distribution. In contrast, contact angle 16 adjacent to the source smaller than contact angle 15 adjacent to the drain can reduce the size of gate layer 11 and thus reduce the gate capacitance (gate-source capacitance and the like). The gate-source capacitance is a parameter that is directly linked to the operating speed of the nitride semiconductor device. Accordingly, reducing the gate capacitance enables the nitride semiconductor device to operate at a higher speed.

### [Production Method]

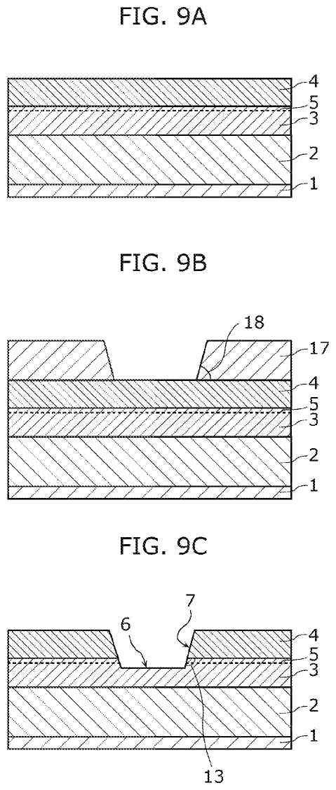

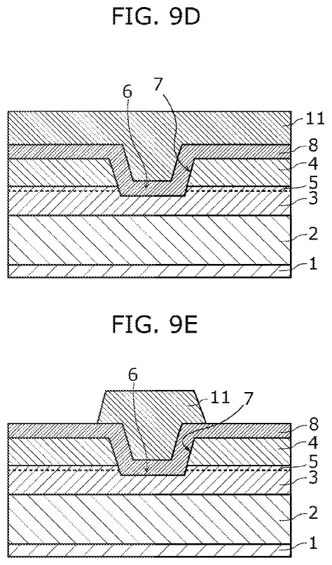

Next, a production method for nitride semiconductor device 100 according to the embodiment illustrated in FIG. 1 will be described with reference to FIGS. 9A to 9E. FIGS. 9A to 9E are cross-sectional views each illustrating a cross-sectional structure of nitride semiconductor device 100 according to this embodiment in a process of the production method. The configuration of this production method described herein is minimal, and this should not be construed as limiting the present disclosure. Moreover, the order of this production method is not limited to the configuration.

First, using a known epitaxial growth technique, such as MOCVD, appropriate buffer layer 2 (for example, a single layer film composed of a Group III nitride semiconductor including GaN, AlGaN, AlN, InGaN, InN, and AlInGaN or a multilayer film composed thereof) is formed on substrate 1 composed of Si (or, for example, a substrate composed of sapphire, SiC, GaN, AlN, or the like) having an appropriate (111) plane. Channel layer 3 composed of GaN (or, for example, a single layer film composed of a Group III nitride semiconductor including InGaN, InN, AlGaN, and AlInGaN or a multilayer film composed thereof) is then formed on buffer layer 2. First barrier layer 4 composed of AlGaN (or, for example, a Group III nitride semiconductor including GaN, InGaN, AlGaN, AlN, and AlInGaN) is then formed on channel layer 3 (see FIG. 9A). In the case where first barrier layer 4 has a band gap larger than that of channel layer 3 and where first barrier layer 4 and channel layer 3 are composed of AlGaN and GaN, respectively, piezoelectric charges produced by the difference in lattice constant between AlGaN and GaN and the difference in band gap between AlGaN and GaN cause high-concentration 2DEG layer 5 to be generated in channel layer 3 adjacent to the interface between first barrier layer 4 and channel layer 3.

Next, resist patterns 17 are formed to form recess 6 using a known photolithographic technique (see FIG. 9B). Here, resist patterns 17 are post-baked as a way to make the angles of side walls 7 of the recess gentler to increase contact angles 13 to more than or equal to 140°. Post-baking temperature varies depending on the resist type. However, the post-baking is performed within a range from about 120° C. to 160° C. for a period of 1 to 30 minutes. This causes the side walls of resist patterns 17 to lie down and reduces taper angles 18 of resist patterns 17. Recess 6 is formed using a dry etching technique, such as inductively coupled plasma reactive ion etching (ICP-RIE). In a case where the dry etching conditions are highly anisotropic, taper angles 18 of resist patterns 17 are transferred to the angles at the lower ends of the side walls of first barrier layer 4 facing recess 6 substantially as they are. It is desirable that taper angles 18 of resist patterns 17 are less than or equal to 60°. However, smaller taper angles 18 of resist patterns 17 increase the opening length of recess 6 adjacent to the upper end of recess 6. This causes gate layer 11 formed afterward and covering recess 6 to be larger, and thus increases the gate capacitance. Accordingly, it is desirable that taper angles 18 of resist patterns 17 be more than or equal to 30° at the smallest.

Moreover, in this method, the width of resist patterns 17 from recess 6 to adjacent recess 6 affects taper angles 18 of resist patterns 17. This is because the post-baking causes resist patterns 17 to contract and be pulled. Taper angles 18 of resist patterns 17 become smaller as the width of resist patterns 17 from recess 6 to adjacent recess 6 decreases. In the case where the etching conditions are highly anisotropic, taper angles 18 of resist patterns 17 are transferred to contact angles 13 of recess 6 substantially as they are. Thus, it is desirable that the post-baking be sufficiently performed such that taper angles 18 of resist patterns 17 on both sides of recess 6 become about the same (within ±20° if possible).

As another way to increase contact angles 13 at which side walls 7 of the recess and the interface between first barrier layer 4 and channel layer 3 meet, conditions under which many polymeric products are created in the dry etching are used. The polymeric products adhering to the side walls of resist patterns 17 and side walls 7 of the recess during the dry etching reduce the etching rate of side walls 7 of the recess and, as a result, increase contact angles 13.

As described above, recess 6 with large contact angles 13 is formed by post-baking resist patterns 17 or using dry etching conditions under which many polymeric products are created, or both, or by other methods. It is desirable that contact angles 13 range from 140° to less than 180°. The recess needs to be sufficiently deep to pass through first barrier layer 4 at any points within the wafer surface such that the bottom of the recess reaches channel layer 3. It is desirable that the penetration depth be at least 0.5 nm or more considering a margin for the penetration depth from the bottom surface of first barrier layer 4. Moreover, in a case where the recess is too deep, 2DEG layer 5 curves significantly and acquires resistance. Accordingly, it is desirable that the depth of the recess range from to 100 nm. Subsequently, resist patterns 17 are removed using, for example, a known oxygen ashing technique or a known organic resist removal technique (see FIG. 9C).

Subsequently, using MOCVD, for example, second barrier layer 8 composed of AlGaN (or, for example, a Group III nitride semiconductor including GaN, InGaN, AlGaN, AlN, and AlInGaN) is regrown to cover recess 6, side walls 7 of the recess, and the upper surface of first barrier layer 4, and gate layer 11 (or, for example, a Group III nitride semiconductor including p-InGaN, p-AlGaN, p-AlInGaN, i-GaN, i-InGaN, i-AlGaN, i-AlInGaN, n-GaN, n-InGaN, n-AlGaN, and n-AlInGaN) is regrown in succession (see FIG. 9D). Gate layer 11 may be composed of p-GaN containing Mg, composed of i-GaN (Insulated-GaN, or, for example, a Group III nitride semiconductor including i-InGaN, i-InN, i-AlGaN, and i-AlInGaN) containing C or the like, or composed of n-GaN (or, for example, a Group III nitride semiconductor including n-InGaN, n-InN, n-AlGaN, and n-AlInGaN) containing an n-type impurity, such as Si. As illustrated in FIG. 9D, second barrier layer 8 containing Al grows to a film thickness that is mostly uniform in perpendicular directions along recess 6, side walls 7 of the recess, and the upper surface of first barrier layer 4, or grows to a film thickness slightly smaller in the perpendicular direction only at the parts along side walls 7 of the recess. In contrast, gate layer 11 composed of GaN, which does not contain Al, flattens out to fill in recess 6 as illustrated in FIG. 9D.

In the case where second barrier layer 8 also has a band gap larger than that of channel layer 3 and where second barrier layer 8 and channel layer 3 are composed of AlGaN and GaN, respectively, piezoelectric charges produced by the difference in lattice constant between AlGaN and GaN and the difference in band gap between AlGaN and GaN cause a high-concentration 2DEG layer to be generated in channel layer 3 adjacent to the interface between second barrier layer 8 and channel layer 3. However, in the case where gate layer 11 is composed of a p-type Group III nitride semiconductor, a p-n junction is formed immediately under gate layer 11, and the 2DEG layer in channel layer 3 adjacent to the interface between second barrier layer 8 and channel layer 3 is depleted while the gate voltage is not applied to gate layer 11. This causes the device to enter the normally off state. At that moment, in the case where second barrier layer 8 is composed of AlGaN and where the Al composition in AlGaN of second barrier layer 8 is 20%, the film thickness of the AlGaN, which may vary depending on the set threshold voltage (Vth), needs to be within the range from 10 to 25 nm, desirably about 20 nm, at the part immediately under gate layer 11. Moreover, at that moment, in the case where gate layer 11 is composed of p-GaN, the film thickness of gate layer 11 may be within the range from 50 to 500 nm, desirably about 200 nm. In addition, in the case where the p-type impurity is Mg, the doping concentration may be within the range from 1E19 cm⁻³ to 10E19E cm⁻³, desirably 5E19 cm⁻³. The carrier concentration of p-GaN doped with Mg of about 5E19 cm⁻³ substantially ranges from about 1E17 cm⁻³ to about 5E17 cm⁻³ due to the very low activation rate of Mg, which is a few percent or less.

Next, resist patterns are formed using a known photolithographic technique, and gate layer 11 is selectively removed using a known dry etching technique. In the case where gate layer 11 and second barrier layer 8 are composed of p-GaN and AlGaN, respectively, the selectivity of selective dry etching may be about 10 (the etching rate of p-GaN is 10 times higher than that of AlGaN), which is not high. In this case, p-GaN other than gate layer 11 needs to be completely removed by removal of regions other than gate layer 11 and over-etching to second barrier layer 8 (not illustrated). This is because gate layer 11 remaining on second barrier layer 8 increases the gate leakage current. It is desirable that the over-etching depth range from 0 to 40 nm, and second barrier layer 8 in the regions other than gate layer 11 may be completely removed.

Subsequently, in the case where gate layer 11 contains Mg, which is a p-type impurity, activation annealing is performed in nitrogen gas at 800° C. for about 30 minutes to activate Mg (not illustrated). This activation annealing breaks hydrogen bonds that inactivate Mg, which is a p-type element, and increases the activation rate of Mg. As a result, gate layer 11 containing the p-type impurity depletes the 2DEG layer in channel layer 3 adjacent to the interface between second barrier layer 8 and channel layer 3 by the p-n junction while the gate voltage is not applied to gate layer 11 (see FIG. 9E).

Subsequently, source electrode 9 and drain electrode 10 are formed at positions away from gate layer 11 using a known photolithographic technique, vapor deposition technique, lift-off technique, sputtering technique, dry etching technique, or the like. Source electrode 9 and drain electrode 10 each may be an electrode composed of one or a combination of two or more of metals including Ti, Al, Mo, and Hf in ohmic contact with 2DEG layer 5, first barrier layer 4, second barrier layer 8, or channel layer 3, and need only be electrically connected to 2DEG layer 5. For example, source electrode 9 and drain electrode 10 may be disposed on the surface of second barrier layer 8 or first barrier layer 4, and may be in contact with 2DEG layer 5, first barrier layer 4, or channel layer 3 using a known ohmic recess technique (not illustrated). Source electrode 9 and drain electrode 10 may be annealed for contact resistance reduction.

Finally, gate electrode 12 is formed using a known photolithographic technique, vapor deposition technique, lift-off technique, sputtering technique, dry etching technique, or the like (see FIG. 1). Gate electrode 12 need only be an electrode composed of one or a combination of two or more of metals including Ti, Ni, Pd, Pt, Au, W, WSi, Ta, TiN, Al, Mo, Hf, and Zr. In a case where gate layer 11 is of the p-type, gate electrode 12 may be in ohmic contact or Schottky contact with gate layer 11. However, since ohmic contact increases the reliability of the gate electrode, it is desirable that an electrode composed of one or a combination of two or more of metals including Ni, Pt, Pd, Au, Ti, Cr, In, Sn, and Al, which have low contact resistances, be used as gate electrode 12.

### [Planar Structure]

Next, a planar structure of nitride semiconductor device 100 according to this embodiment will be described. Nitride semiconductor devices 101, 102, and 103 respectively illustrated in FIGS. 6 to 8 according to the variations also have an identical planar structure, and the explanations thereof will be omitted.

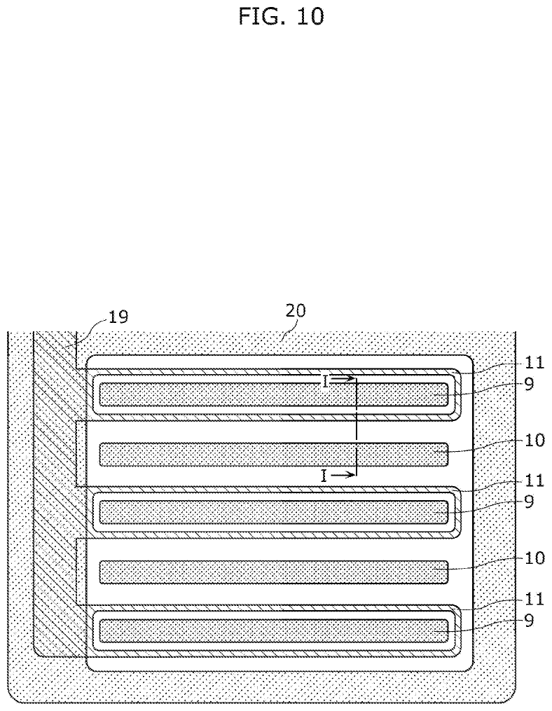

FIG. 10 is a plan view of the planar structure of nitride semiconductor device 100 according to this embodiment. FIG. 10 is a plan view obtained when FIG. 1 is viewed from above, and illustrates a state where source electrodes 9 and drain electrodes 10 have been formed before gate electrode 12 is formed. For example, FIG. 1 is a cross-section taken along line I-I in FIG. 10. The structure illustrated herein is minimal, and this should not be construed as limiting the present disclosure.

Each gate layer 11 is formed to surround corresponding source electrode 9. This forms p-n junctions that cause the device to be normally off immediately under gate layers 11 between the sources and the drains and thus cuts off the leakage paths between the sources and the drains while the device is off to reduce the source-drain leakage current. Moreover, gate layers 11 are aggregated (aggregated on the left side in FIG. 10). Gate aggregate 19 is connected to a gate pad in element isolation region 20 (not illustrated). Although element isolation region 20 lies outside source electrodes 9, drain electrodes 10, and gate layers 11, parts of ends of aggregated gate layers 11 (on the left side in the drawing) and a part of gate aggregate 19 are in element isolation region 20. Multiple sets of source electrode 9 and drain electrode 10 are repeatedly formed as illustrated in FIG. 10. However, the outermost electrodes (on the top and the bottom in FIG. 10) may be source electrodes 9 to relax the electric field distribution compared with the outside of element isolation region 20 for greater reliability.

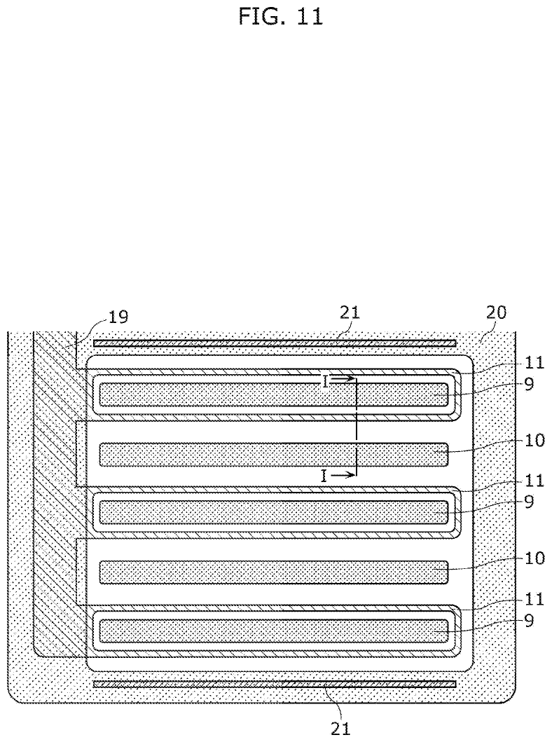

As explained in the production method using FIGS. 9A to 9E, when recess 6 is formed immediately under gate layer 11, the width of the resist from recess 6 to adjacent recess 6 affects taper angles 18 of resist patterns 17. This is because the post-baking causes resist patterns 17 to contract and be pulled. Taper angles 18 of resist patterns 17 become smaller as the width of resist patterns 17 from recess 6 to adjacent recess 6 decreases. When dry etching is performed using resist patterns 17 under highly anisotropic conditions, taper angles 18 of resist patterns 17 are transferred to contact angles 13 of recess 6 substantially as they are. As a result, in a finger pattern including multiple recesses 6 arranged in parallel, only outer contact angles 13 of fingers of outermost recesses 6 (on the top and the bottom in FIG. 10) become smaller. To avoid this, in addition to sufficient post-baking to make taper angles 18 of resist patterns 17 on both sides of recess 6 about the same (within ±20° if possible), for example, the fingers of uppermost and lowermost gate layers 11 in the arrangement illustrated in FIG. 10 may be inactivated by ion implantation to be inactivated regions (not illustrated). Alternatively, as illustrated in FIG. 11, dummy gate layers 21 with recesses 6 that are not electrically connected may be desirably laid out in element isolation region 20 further outside the fingers of outermost gate layers 11.

### Other Embodiments

Although the nitride semiconductor device according to one or more aspects has been described above based on an embodiment, the present disclosure is not limited to the embodiment. Forms achieved by making various modifications to the embodiment that are conceivable by a person of skill in the art as well as other forms resulting from combinations of constituent elements from different embodiments are also within the scope of the present disclosure, so long as such forms are within the essence of the present disclosure.

For example, in the embodiment and the variations above, each of the semiconductor layers is composed of a Group III nitride semiconductor. However, this should not be construed as limiting the present disclosure. Moreover, the structures illustrated in the embodiment and the variations above are minimal, and this should not be construed as limiting the present disclosure.

Moreover, for example, the contact angle adjacent to the drain and the contact angle adjacent to the source may be the same or different. Moreover, for example, the side walls of recess 6 (parts of channel layer 3) and the side walls of first barrier layer 4 facing recess 6 may not be continuously connected. Side walls 7 of the recess may be flat slopes or curved surfaces.

Moreover, various modifications, substitutions, additions, omissions, and the like can be made to the embodiments above within the scope of the claims or equivalents thereof.

### INDUSTRIAL APPLICABILITY

The present disclosure can be used as nitride semiconductor devices of which the on-resistance can be reduced, and can be used for, for example, power devices, such as field-effect transistors.

1. A nitride semiconductor device comprising:
a substrate; and
a first nitride semiconductor layer, a second nitride semiconductor layer, and a third nitride semiconductor layer that are disposed above the substrate in stated order, wherein
the first nitride semiconductor layer includes a recess,
the second nitride semiconductor layer has a band gap larger than a band gap of the first nitride semiconductor layer and is disposed in a region other than the recess,
the third nitride semiconductor layer has a band gap larger than the band gap of the first nitride semiconductor layer and covers the first nitride semiconductor layer and the second nitride semiconductor layer including an inner wall of the recess, and
a contact angle at which a side wall of the recess and an interface between the first nitride semiconductor layer and the second nitride semiconductor layer meet ranges from 140° to less than 180°.

2. The nitride semiconductor device according to claim 1, wherein
the contact angle at which the side wall of the recess and the interface between the first nitride semiconductor layer and the second nitride semiconductor layer meet and a contact angle at which an other side wall of the recess on an opposite side and the interface between the first nitride semiconductor layer and the second nitride semiconductor layer meet both range from 140° to less than 180°.

3. The nitride semiconductor device according to claim 1, wherein
an average of the contact angle at which the side wall of the recess and the interface between the first nitride semiconductor layer and the second nitride semiconductor layer meet and a contact angle at which an other side wall of the recess on an opposite side and the interface between the first nitride semiconductor layer and the second nitride semiconductor layer meet ranges from 145° to less than 180°.

4. The nitride semiconductor device according to claim 1, wherein
the contact angle is larger than a taper angle at which a side wall of the second nitride semiconductor layer facing the recess and an upper surface of the second nitride semiconductor layer meet.

5. The nitride semiconductor device according to claim 1, wherein
a taper angle at which a side wall of the second nitride semiconductor layer facing the recess and an upper surface of the second nitride semiconductor layer meet ranges from 120° to less than 180°.

6. The nitride semiconductor device according to claim 1, wherein
a difference between the contact angle and a taper angle at which a side wall of the second nitride semiconductor layer facing the recess and an upper surface of the second nitride semiconductor layer meet is within a range of ±20°.

7. The nitride semiconductor device according to claim 1, wherein
a gradient of a tangent to the side wall of the recess and a gradient of a tangent to a side wall of the second nitride semiconductor layer facing the recess are uniquely determined.

8. The nitride semiconductor device according to claim 1, wherein
an angle formed between the side wall of the recess and a side wall of the second nitride semiconductor layer facing the recess is within a range of 180°±30°.

9. The nitride semiconductor device according to claim 1, wherein
a film thickness of a part of the third nitride semiconductor layer along a side wall of the second nitride semiconductor layer is more than or equal to 50% of a film thickness of a part of the third nitride semiconductor layer along a bottom of the recess in a vertical direction.

10. The nitride semiconductor device according to claim 1, wherein
the third nitride semiconductor layer contains Al, and
an Al composition in the third nitride semiconductor layer is less than or equal to 25%.

11. The nitride semiconductor device according to claim 1, wherein
the third nitride semiconductor layer contains Al, and
an Al composition in the third nitride semiconductor layer varies within a range of ±5%.

12. The nitride semiconductor device according to claim 1, further comprising:
a source electrode and a drain electrode spaced from the recess with the recess disposed therebetween, wherein
a contact angle adjacent to the drain electrode is larger than a contact angle adjacent to the source electrode.
